(19) United States
(12) Patent Application Publication
(10) Pub. No.: US 2026/0075905 A1
(43) Pub. Date: Mar. 12, 2026

(54) DEPOSITION OF N-METAL FILMS

(71) Applicant: Applied Materials, Inc., Santa Clara, CA (US)

(72) Inventors: Srinivas Gandikota, Santa Clara, CA (US); Yixiong Yang, Fremont, CA (US); Tuerxun Ailihumaer, Santa Clara, CA (US); Tengzhou Ma, San Jose, CA (US); Haodong Wang, Sunnyvale, CA (US); Seshadri Ganguli, San Jose, CA (US)

(73) Assignee: Applied Materials, Inc., Santa Clara, CA (US)

(21) Appl. No.: 18/826,297

(22) Filed: Sep. 6, 2024

(51) Int. Cl. H01L 29/40; H01L 21/28; H01L 21/285; H01L 29/423

(52) U.S. Cl. CPC H10D 64/01; H10D 64/0113; H10D 64/01318; H10D 64/01332; H10D 64/512; H10D 64/514; H10D 64/517

(57) ABSTRACT

Provided are semiconductor devices, e.g., transistors, and methods of manufacturing semiconductor devices which achieve NMOS band edge with low resistivity and having improved device performance and reliability. Provided are materials that can be used as effective N-metal films for transistors. Instead of conventional titanium aluminum carbide (TiAlC) based N-metal films, provided are binary/ternary metal carbide films and metal silicide films that may be used as N-metal films with no/minimal high-k (HK) capping layer required.

### TECHNICAL FIELD

Embodiments of the present disclosure pertain to the field of electronic device manufacturing, and in particular, to transistors. More particularly, embodiments of the disclosure are directed to transistors and methods of manufacturing transistors.

### BACKGROUND

Integrated circuits have evolved into complex devices that can include millions of transistors, capacitors, and resistors on a single chip. In the course of integrated circuit evolution, functional density (i.e., the number of interconnected devices per chip area) has generally increased while geometry size (i.e., the smallest component (or line) that can be created using a fabrication process) has decreased.

Transistors are circuit components or elements that are often formed on semiconductor devices. Many transistors may be formed on a semiconductor device in addition to capacitors, inductors, resistors, diodes, conductive lines, or other elements, depending on the circuit design. Integrated circuits incorporate planar field-effect transistors (FETs) in which current flows through a semiconducting channel between a source and a drain, in response to a voltage applied to a control gate.

As device dimensions have shrunk, device geometries and materials have experienced difficulty maintaining switching speeds without incurring failures. Several innovative technologies emerged that allowed chip designers to continue shrinking gate lengths. Control of the dimensions of device structure remains a challenge for present and future technology generations.

Shrinking of the materials currently used as negative metal-oxide-semiconductor (N-MOS) transistors and positive metal-oxide semiconductor (P-MOS) transistors have become a challenge due to change in basic properties, such as threshold voltage (Vt). Additionally, the migration of transistor technology from planar FET to FinFET to GAA devices requires conformal work function layers for multiple threshold voltages (multi-Vt). The Vt tuning range will be limited by the film thickness variation with further scaling down of device sizes.

With the more advanced device scaling, there is a desire to achieve NMOS band edge with low resistivity. With conventional titanium aluminum carbide (TiAlC) N-metal schemes, attempts to increase the percentage of aluminum (Al) to boost work function las led to increases in the percentage of carbon and high resistivity, which makes scaling eWF at lower thickness not viable. High Al in N-metal also leads to high leakage with reducing high-k cap thickness, making it more challenging for scaling.

Accordingly, there is a need for methods of manufacturing electronic devices that achieve NMOS band edge with low resistivity.

### SUMMARY

One or more embodiments are directed to a method of manufacturing a semiconductor device. In some embodiments, the method includes depositing high-κ dielectric layer on a top surface of a channel located between a source and a drain on a substrate; and forming an N-metal region on the high-κ dielectric layer, the N-metal region comprising one or more of a binary metal carbide film, a ternary metal carbide film, and a metal silicide film.

Additional embodiments are directed to a semiconductor device. In some embodiments, the semiconductor device includes: a source region, a drain region, and a channel separating the source region and drain region; a high-κ dielectric layer on a top surface of the channel; and an N-metal region on the high-κ dielectric layer, the N-metal region comprising one or more of a binary metal carbide film, a ternary metal carbide film, and a metal silicide film.

Further embodiments are directed to a non-transitory computer readable medium including instructions, that, when executed by a controller of a processing chamber, cause the processing chamber to perform the operations of: deposit high-κ dielectric layer on a top surface of a channel located between a source and a drain on a substrate; and form an N-metal region on the high-κ dielectric layer, the N-metal region comprising one or more of a binary metal carbide film, a ternary metal carbide film, and a metal silicide film.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements.

FIG. 1 illustrates a process flow diagram of a method according to one or more embodiments;

FIG. 2A illustrates a process flow diagram of a method according to one or more embodiments;

FIG. 2B illustrates a process flow diagram of a method according to one or more embodiments;

FIG. 2C illustrates a process flow diagram of a method according to one or more embodiments;

FIG. 3A illustrates a cross-sectional view of a semiconductor substrate according to one or more embodiments;

FIG. 3B illustrates a cross-sectional view of a semiconductor substrate according to one or more embodiments;

FIG. 3C illustrates a cross-sectional view of a semiconductor substrate according to one or more embodiments;

FIG. 3D illustrates a cross-sectional view of a semiconductor substrate according to one or more embodiments;

FIG. 3E illustrates a cross-sectional view of a semiconductor substrate according to one or more embodiments; and

FIG. 4 illustrates a cluster tool according to one or more embodiments of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “about” as used herein means approximately or nearly and in the context of a numerical value or range set forth means a variation of ±15%, or less, of the numerical value. For example, a value differing by ±14%, ±10%, ±5%, ±2%, or ±1%, would satisfy the definition of about.

As used in this specification and the appended claims, the term “substrate” or “wafer” refers to a surface, or portion of a surface, upon which a process acts. It will also be understood by those skilled in the art that reference to a substrate can refer to only a portion of the substrate unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface.

As used in this specification and the appended claims, the terms “precursor”, “reactant”, “reactive gas” and the like are used interchangeably to refer to any gaseous species that can react with the substrate surface.

The term “on” indicates that there is direct contact between elements. The term “directly on” indicates that there is direct contact between elements with no intervening elements.

“Atomic layer deposition” or “cyclical deposition” as used herein refers to the sequential exposure of two or more reactive compounds to deposit a layer of material on a substrate surface. The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time-delay. Next, a second precursor or compound B is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In an embodiment of a spatial ALD process, a first reactive gas and second reactive gas (e.g., nitrogen gas) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

Transistors are circuit components or elements that are often formed on semiconductor devices. Depending upon the circuit design, in addition to capacitors, inductors, resistors, diodes, conductive lines, or other elements, transistors are formed on a semiconductor device. Generally, a transistor includes a gate formed between source and drain regions. In one or more embodiments, the source and drain regions include a doped region of a substrate, such as a semiconductor substrate, and exhibit a doping profile suitable for a particular application. The gate is positioned over the channel region and includes a gate dielectric interposed between a gate electrode and the channel region in the semiconductor substrate.

As used herein, the term “field effect transistor” or “FET” refers to a transistor that uses an electric field to control the electrical behavior of the device. Field effect transistors are voltage-controlled devices where their current carrying ability is changed by applying an electric field. Field effect transistors generally display very high input impedance at low temperatures. The conductivity between the drain and source terminals is controlled by an electric field in the device, which is generated by a voltage difference between the body and the gate of the device. The FET's three terminals are source(S), through which the carriers enter the channel; drain (D), through which the carriers leave the channel; and gate (G), the terminal that modulates the channel conductivity. Conventionally, current entering the channel at the source(S) is designated Is and current entering the channel at the drain (D) is designated ID. Drain-to-source voltage is designated VDs. By applying voltage to gate (G), the current entering the channel at the drain (i.e., ID) can be controlled.

The metal-oxide-semiconductor field-effect transistor (MOSFET) is a type of field-effect transistor (FET) and is used in integrated circuits and high-speed switching applications. MOSFET has an insulated gate, whose voltage determines the conductivity of the device. This ability to change conductivity with the amount of applied voltage is used for amplifying or switching electronic signals. A MOSFET is based on the modulation of charge concentration by a metal-oxide-semiconductor (MOS) capacitance between a body electrode and a gate electrode located above the body and insulated from all other device regions by a gate dielectric layer. Compared to the MOS capacitor, the MOSFET includes two additional terminals (source and drain), each connected to individual highly doped regions that are separated by the body region. These regions can be either p or n type, but they are both of the same type, and of opposite type to the body region. The source and drain (unlike the body) are highly doped as signified by a “+” sign after the type of doping.

If the MOSFET is an n-channel or nMOS FET, then the source and drain are n+ regions and the body is a p-type substrate region. If the MOSFET is a p-channel or pMOS FET, then the source and drain are p+ regions and the body is a n-type substrate region. The source is so named because it is the source of the charge carriers (electrons for n-channel, holes for p-channel) that flow through the channel; similarly, the drain is where the charge carriers leave the channel.

A nMOS FET is made up of a n-type source and drain and a p-type substrate. When a voltage is applied to the gate, holes in the body (p-type substrate) are driven away from the gate. This allows forming an n-type channel between the source and the drain and a current is carried by electrons from source to the drain through an induced n-type channel. Logic gates and other digital devices implemented using NMOSs are said to have NMOS logic. There are three modes of operation in a NMOS called the cut-off, triode and saturation. Circuits with NMOS logic gates dissipate static power when the circuit is idling, since DC current flows through the logic gate when the output is low.

A pMOS FET is made up of p-type source and drain and an n-type substrate. When a positive voltage is applied between the source and the gate (negative voltage between gate and source), a p-type channel is formed between the source and the drain with opposite polarities. A current is carried by holes from source to the drain through an induced p-type channel. A high voltage on the gate will cause a PMOS not to conduct, while a low voltage on the gate will cause it to conduct. Logic gates and other digital devices implemented using PMOS are said to have PMOS logic. PMOS technology is low cost and has a good noise immunity.

In a NMOS, carriers are electrons, while in a PMOS, carriers are holes. When a high voltage is applied to the gate, NMOS will conduct, while PMOS will not. Furthermore, when a low voltage is applied in the gate, NMOS will not conduct and PMOS will conduct. NMOS are considered to be faster than PMOS, since the carriers in NMOS, which are electrons, travel twice as fast as holes, which are the carriers in PMOS. But PMOS devices are more immune to noise than NMOS devices. Furthermore, NMOS ICs would be smaller than PMOS ICs (that give the same functionality), since the NMOS can provide one-half of the impedance provided by a PMOS (which has the same geometry and operating conditions).

As used herein, the term “fin field-effect transistor (FinFET)” refers to a MOSFET transistor built on a substrate where the gate is placed on two, three, or four sides of the channel or wrapped around the channel, forming a double gate structure. FinFET devices have been given the generic name FinFETs because the source/drain region forms “fins” on the substrate. FinFET devices have fast switching times and high current density.

As used herein, the term “gate all-around (GAA),” is used to refer to an electronic device, e.g., a transistor, in which the gate material surrounds the channel region on all sides. The channel region of a GAA transistor may include nanowires or nano-slabs or nano-sheets, bar-shaped channels, or other suitable channel configurations known to one of skill in the art. In one or more embodiments, the channel region of a GAA device has multiple horizontal nanowires or horizontal bars vertically spaced, making the GAA transistor a stacked horizontal gate-all-around (hGAA) transistor.

As used herein, the term “nanowire” refers to a nanostructure, with a diameter on the order of a nanometer (10⁻⁹ meters). Nanowires can also be defined as the ratio of the length to width being greater than 1000. Alternatively, nanowires can be defined as structures having a thickness or diameter constrained to tens of nanometers or less and an unconstrained length. Nanowires are used in transistors and some laser applications, and, in one or more embodiments, are made of semiconducting materials, metallic materials, insulating materials, superconducting materials, or molecular materials. In one or more embodiments, nanowires are used in transistors for logic CPU, GPU, MPU, and volatile (e.g., DRAM) and non-volatile (e.g., NAND) devices. As used herein, the term “nanosheet” refers to a two-dimensional nanostructure with a thickness in a scale ranging from about 0.1 nm to about 1000 nm, or from 0.5 nm to 500 nm, or from 0.5 nm to 100 nm, or from 1 nm to 500 nm, or from 1 nm to 100 nm, or from 1 nm to 50 nm.

Embodiments of the present disclosure advantageously provide semiconductor devices and methods of manufacturing semiconductor devices which achieve NMOS band edge with low resistivity and having improved device performance and reliability. One or more embodiments are advantageously directed to materials that can be used as effective N-metal films for transistors, e.g., FinFET, NMOS, and the like. In one or more embodiments, instead of conventional titanium aluminum carbide (TiAlC) based N-metal films, advantageously provided are binary/ternary metal carbide films and metal silicide films that may be used as N-metal films with no/minimal high-k (HK) capping layer required. In one or more embodiments, provided is an integrated process scheme with a capping layer that prevents N-metal oxidation and Al/N/C/O/Si/F/Cl diffusion, and which provides low resistivity and band edge work function.

The embodiments of the disclosure are described by way of the Figures, which illustrate devices (e.g., transistors) and processes for forming transistors in accordance with one or more embodiments of the disclosure. The processes shown are merely illustrative possible uses for the disclosed processes, and the skilled artisan will recognize that the disclosed processes are not limited to the illustrated applications.

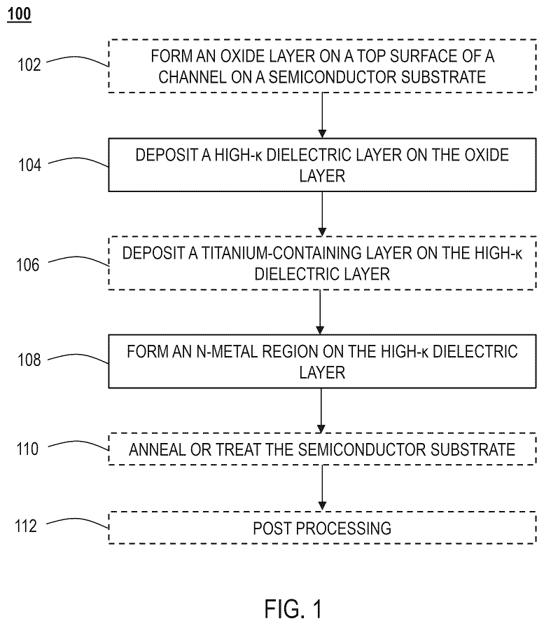

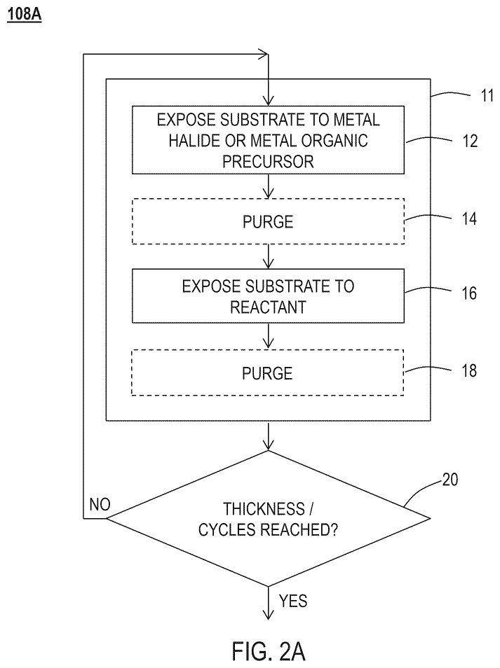

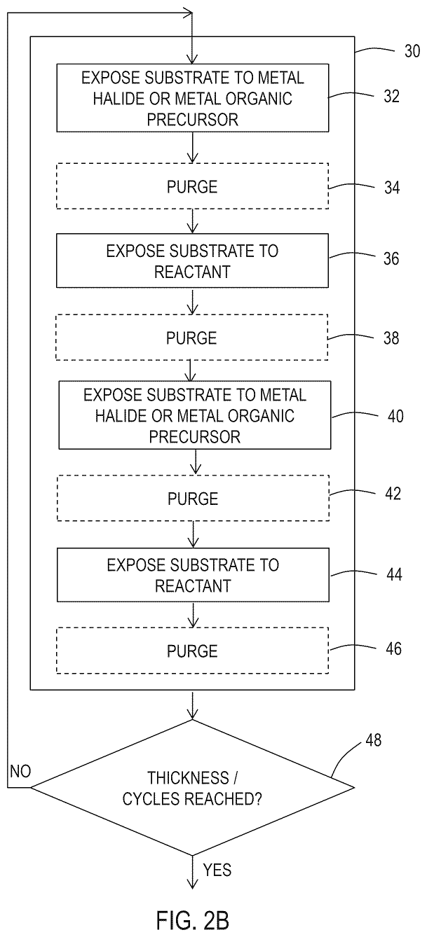

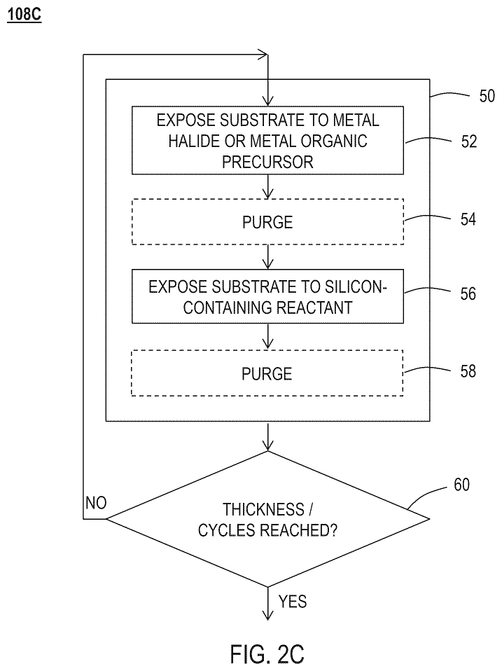

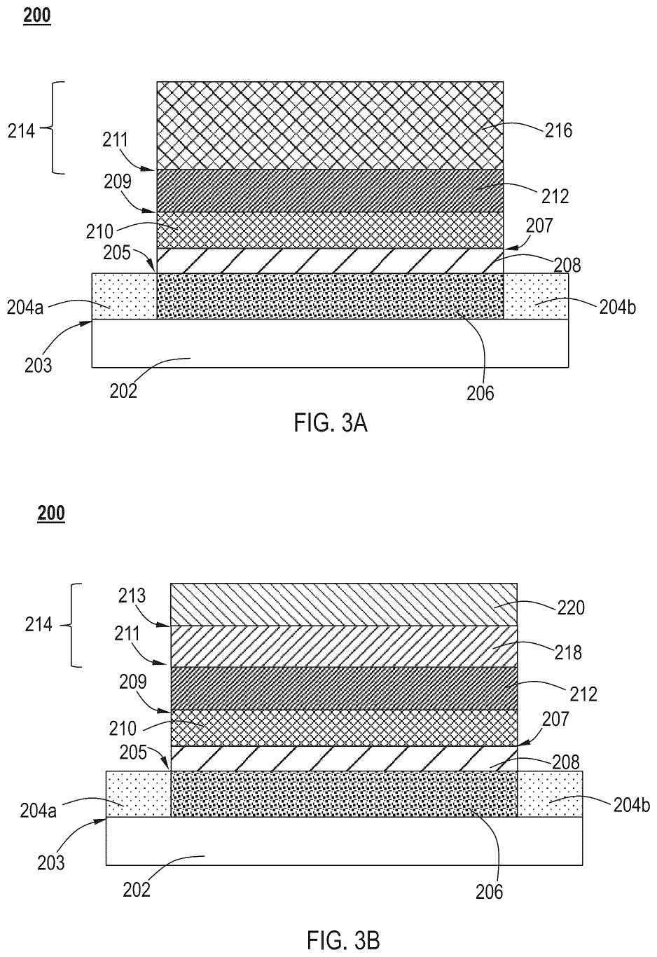

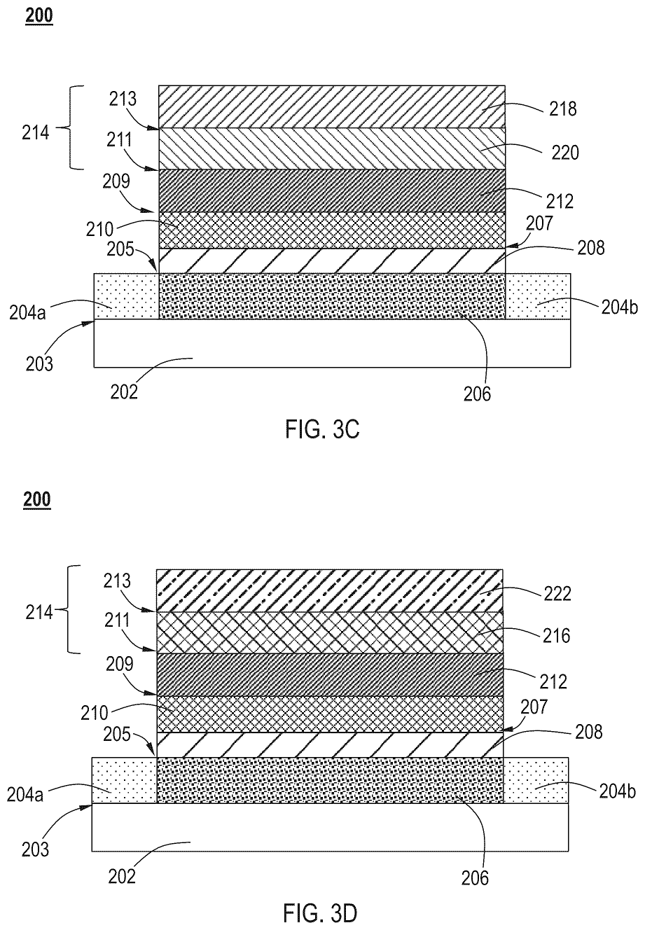

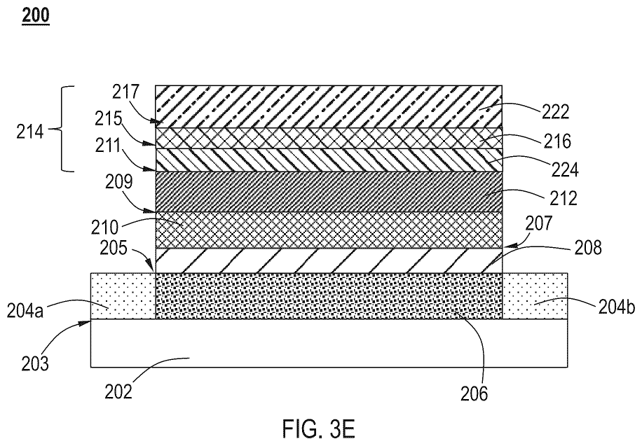

FIG. 1 depicts a process flow diagram of method 100 of manufacturing a semiconductor device in accordance with one or more embodiments of the present disclosure. FIGS. 2A-2C depict process flow diagrams of methods 10A, 10B, 10C of depositing an N-metal film in accordance with one or more embodiments of the present disclosure. FIGS. 3A-3E are cross-sectional views of a semiconductor substrate according to one or more embodiments.

Referring to FIG. 1, method 100 of manufacturing a semiconductor device begins at operation 102 by optionally forming an interfacial layer or oxide layer on a top surface of a channel located between a source and a drain on a semiconductor substrate. In some embodiments, the channel may already have an oxide layer thereon. At operation 104, a high-κ dielectric layer is deposited on the interfacial layer. At operation 106, a titanium-containing layer is optionally deposited on the high-κ dielectric layer. At operation 108, an N-metal region is formed on the high-κ layer (or on the titanium-containing layer, if present). At operation 110, method 100 optionally includes annealing the semiconductor substrate. At operation 112, method 100 optionally includes one or more post processing step.

In some embodiments, at operation 102, the interfacial layer is deposited using a deposition technique, such as, but not limited to, ALD, CVD, PVD, MBE, MOCVD, spin-on, or other deposition techniques known to the skilled artisan. In one or more embodiments, the interfacial layer may be formed by etching and an oxide forming on the surface. In other embodiments, the oxide layer may be formed on the channel by oxidation of the surface of the channel.

In some embodiments, at operation 102, a wet chemistry technique is performed to form the interfacial layer. The wet chemistry technique may be any suitable technique known to the skilled artisan. In some embodiments, the wet chemistry technique includes a pre-clean process. In some embodiments, the pre-clean process includes using a solution comprising one or more of ozone, ammonium hydroxide, or hydrogen peroxide. In some embodiments, the pre-clean process includes using a solution without ozone, ammonium hydroxide or hydrogen peroxide.

In some embodiments, at operation 104, the high-κ dielectric layer is deposited using a deposition technique, such as, but not limited to, ALD, CVD, PVD, MBE, MOCVD, spin-on, or other deposition techniques known to the skilled artisan. In some embodiments, at operation 104, the high-κ dielectric layer is conformally deposited by ALD.

In some embodiments, at operation 106, a titanium-containing layer is optionally deposited on the high-κ dielectric layer using a deposition technique, such as, but not limited to, ALD, CVD, PVD, MBE, MOCVD, spin-on, or other deposition techniques known to the skilled artisan. In some embodiments, at operation 106, the titanium-containing layer is conformally deposited by ALD.

In one or more embodiments, at operation 108, an N-metal layer is deposited on the high-κ dielectric layer (or on the titanium-containing layer, if present). The N-metal layer may be deposited according to any suitable method. In one or more embodiments, the N-metal layer is deposited according to the methods 108A, 108B, 108C of FIGS. 2A, 2B, and 2C as described herein.

Referring to FIG. 1 in one or more embodiments, at operation 110, method 100 optionally includes annealing the semiconductor substrate or a radical treatment of the semiconductor substrate. In some embodiments, the semiconductor substrate is at a temperature of less than or equal to 500° C. In some embodiments, the semiconductor substrate is annealed or treated with a radical in an ambient atmosphere of hydrogen (H₂) at a low temperature to avoid a counter-dipole formation with titanium, tantalum, and aluminum.

In one or more embodiments, annealing the semiconductor substrate at operation 110 includes a rapid thermal process (RTP) and/or a radical treatment process. The RTP and/or radical treatment may be any suitable process known to the skilled artisan. Without intending to be bound by theory, the RTP and/or radical treatment is believed to densify and improve the physical properties of the deposited layers. In some embodiments, the radical treatment involves treating the semiconductor substrate in an ambient atmosphere of hydrogen (H₂) to remove carbon (C) from the N-metal region.

Referring to FIG. 1, in some embodiments, at operation 112, the method 100 optionally includes one or more post processing operation. In some embodiments, the post processing operation may include performing an etching process to remove one or more layer. The etching process can be any suitable etching process known to the skilled artisan. In some embodiments, the etching process comprises a wet etch process or a dry etch process. In some embodiments, the etching process comprises a wet etch process. In some embodiments, the wet etch process includes a pre-clean process. In some embodiments, the pre-clean process includes using one or more of ammonium hydroxide (NH₄OH) or water (H₂O). In some embodiments, the water (H₂O) is de-ionized water (DI). In some embodiments, the pre-clean process includes using a ratio of DI:NH₄OH in a range of from 100:1 DI:NH₄OH to 5:1 DI:NH₄OH.

In one or more embodiments, one or more layer is removed and a gate comprising one or more of a gate metal (not illustrated) or a gate contact (not illustrated) may optionally be formed or deposited on the exposed surface of, for example, the high-κ dielectric layer. In one or more embodiments, the gate metal may be any suitable material known to one of skill in the art. In one or more embodiments, the gate metal comprises one or more of nitrogen (N), copper (Cu), cobalt (Co), tungsten (W), titanium (Ti), tantalum (Ta), molybdenum (Mo), nickel (Ni), ruthenium (Ru), iridium (Ir), aluminum (Al), or platinum (Pt). In one or more specific embodiments, the gate metal comprises a metal selected from one or more of nitrogen (N), cobalt (Co), tungsten (W), titanium (Ti), molybdenum (Mo), nickel (Ni), ruthenium (Ru), iridium (Ir), aluminum (Al), or platinum (Pt). In other specific embodiments, the gate metal comprises a metal or a metal alloy selected from one or more of nitrogen (N), cobalt (Co), tungsten (W), titanium (Ti), molybdenum (Mo), ruthenium (Ru), hafnium (Hf), or zirconium (Zr). In embodiments where the gate metal is formed on the high-κ dielectric layer, the gate metal is deposited as a gate metal layer (not shown). The gate metal layer may be deposited using a deposition technique, such as, but not limited to, ALD, CVD, PVD, MBE, MOCVD, spin-on, or other insulating layer deposition techniques known to the skilled artisan. The gate metal layer may have any suitable thickness. In some embodiments, the gate metal layer has a thickness in a range of from 1 nm to 3 nm. In embodiments where the gate metal is formed on the high-κ dielectric layer, the gate metal layer has a capping layer thereon. The capping layer on the gate metal layer may have any suitable thickness. In some embodiments, the capping layer on the gate metal layer has a thickness in a range of from 0.5 nm to 2 nm, including in a range from 0.6 nm to 1.9 nm, in a range of from 0.7 nm to 1.8 nm, in a range of from 0.8 nm to 1.7 nm, in a range of from 0.9 nm to 1.6 nm, in a range of from 1 nm to 1.5 nm, in a range of from 1.1 nm to 1.4 nm, or in a range of from 1.2 nm to 1.3 nm.

In one or more embodiments, the gate contact may be any suitable material known to the skilled artisan. In one or more embodiments, the gate contact comprises an element or an alloy selected from one or more of nitrogen (N), copper (Cu), cobalt (Co), tungsten (W), titanium (Ti), molybdenum (Mo), nickel (Ni), ruthenium (Ru), iridium (Ir), tantalum (Ta), aluminum (Al), or platinum (Pt).

FIGS. 3A-3E are cross-sectional views of an electronic device (e.g., a transistor) 200 according to one or more embodiments. The electronic devices 200 shown in FIGS. 3A-3E may be manufactured by the method 100 illustrated in FIG. 1. The N-metal region 214 illustrated in FIGS. 3A-3E may be formed by any of the methods 108A, 108B, 108C illustrated in FIGS. 2A-2C and described herein.

With reference to FIGS. 3A-3E, in one or more embodiments, the electronic device 200 comprises a semiconductor substrate 202 having a top surface 203. In one or more embodiments, the semiconductor substrate 202 can be any suitable substrate material. In one or more embodiments, the semiconductor substrate 202 comprises a semiconductor material, e.g., silicon (Si), carbon (C), germanium (Ge), silicon germanium (SiGe), gallium arsenide (GaAs), indium phosphate (InP), indium gallium arsenide (InGaAs), indium aluminum arsenide (InAlAs), germanium (Ge), silicon germanium (SiGe), copper indium gallium selenide (CIGS), other semiconductor materials, or any combination thereof. In one or more embodiments, the semiconductor substrate 202 comprises one or more of silicon (Si), germanium (Ge), gallium (Ga), arsenic (As), indium (In), phosphorus (P), copper (Cu), or selenium (Se). Although a few examples of materials from which the semiconductor substrate 202 may be formed are described herein, any material that may serve as a foundation upon which passive and active electronic devices (e.g., transistors, memories, capacitors, inductors, resistors, switches, integrated circuits, amplifiers, optoelectronic devices, or any other electronic devices) may be built falls within the spirit and scope of the present disclosure.

In one or more embodiments, the semiconductor substrate 202 is a p-type or n-type substrate. As used herein, the term “n-type” refers to semiconductors that are created by doping an intrinsic semiconductor with an electron donor element during manufacture. The term n-type comes from the negative charge of the electron. In n-type semiconductors, electrons are the majority carriers and holes are the minority carriers. As used herein, the term “p-type” refers to the positive charge of a well (or hole). As opposed to n-type semiconductors, p-type semiconductors have a larger hole concentration than electron concentration. In p-type semiconductors, holes are the majority carriers and electrons are the minority carriers.

In some embodiments, a source region 204a is on the top surface 203 of the semiconductor substrate 202. In one or more embodiments, the source region 204a has a source and a source contact (not illustrated). A drain region 204b is on the top surface 203 of the semiconductor substrate 202 opposite the source region 204a. In one or more embodiments, the drain region 204b has a drain and a drain contact (not illustrated).

In one or more embodiments, the source region 204a and/or the drain region 204b can be any suitable material known to the skilled artisan. In one or more embodiments, the source region 204a and/or the drain region 204b may have more than one layer. For example, the source region 204a and/or the drain region 204b may independently comprise three layers. In one or more embodiments, the source region 204a and the drain region 204b may independently comprise one or more of copper (Cu), cobalt (Co), tungsten (W), titanium (Ti), molybdenum (Mo), nickel (Ni), ruthenium (Ru), silver (Ag), gold (Au), iridium (Ir), platinum (Pt), phosphorus (P), germanium (Ge), silicon (Si), aluminum (Al), or zirconium (Zr). In some embodiments, the source region 204a and the drain region 204b may independently comprise a bottom layer of silicon with doped epi (e.g. SiGe, SiP, and the like), a second layer of silicide, which may contain nickel (Ni), titanium (Ti), aluminum (Al), and the like, and a third, or top, layer which may be a metal such as, but not limited to, cobalt, tungsten, ruthenium, and the like.

In some embodiments, the source region 204a and the drain region 204b may be raised source/drain regions formed by epitaxial growth. In one or more embodiments, the source contact and/or the drain contact may independently be selected from one or more of nitrogen (N), copper (Cu), cobalt (Co), tungsten (W), titanium (Ti), molybdenum (Mo), nickel (Ni), ruthenium (Ru), silver (Ag), gold (Au), iridium (Ir), tantalum (Ta), or platinum (Pt). In one or more embodiments, formation of the source contact and/or the drain contact is conducted by any suitable process known to the skilled artisan, including, but not limited to ALD, CVD, PVD, MBE, MOCVD, spin-on, or other insulating layer deposition techniques known to the skilled artisan.

In one or more embodiments, a channel 206 is located between the source 204a and the drain 204b. In one or more embodiments, the channel 206 comprises any suitable material known to the skilled artisan. In some embodiments, the channel 206 comprises silicon (Si).

In one or more embodiments, an oxide layer 208 (or an interfacial layer) is formed on a top surface 205 of the channel 206. The oxide layer 208 may be formed by any suitable method as described with respect to operation 102 of method 100 in FIG. 1. In some embodiments, the oxide layer 208 is formed by oxidation of the channel 206. In embodiments where the channel 206 comprises silicon (Si), the oxide layer 208 may comprise silicon oxide (SiOx).

In one or more embodiments, a high-κ dielectric layer 210 is formed on a top surface 207 of the oxide layer 208 according to operation 104 of method 100, as illustrated in FIG. 1. In one or more embodiments, the high-κ dielectric layer 210 can be any suitable high-κ dielectric material known to the skilled artisan. In one or more embodiments, the high-κ dielectric layer 210 comprises one or more of a lanthanum oxide (LaOx), lanthanum silicate, hafnium oxide (HfOx), hafnium silicate, hafnium silicon oxynitride (HfSiON), zirconium oxide (ZrOx), zirconium silicate, hafnium zirconium oxide (HfZrOx). In other embodiments, the high-κ dielectric layer 210 comprises an oxide doped with a metal selected from zirconium, lanthanum, cerium, titanium, or combinations thereof, or a spin-on dielectric.

The high-κ dielectric layer 210 may have any suitable thickness. In some embodiments, the high-k dielectric layer 210 has a thickness in a range of from >0 Å to 20 Å, including in a range of from 1 Å to 20 Å, in a range of from 1 Å to 15 Å, in a range of 5 Å to 20 Å, or in a range of from 5 Å to 15 Å.

In one or more embodiments, a titanium-containing layer 212 is optionally formed on a top surface 209 of the high-κ dielectric layer 210 according to operation 106 of method 100, as illustrated in FIG. 1. In one or more embodiments, the titanium-containing layer 212 may comprise any suitable titanium-containing material known to the skilled artisan. In one or more embodiments, the titanium-containing layer 212 comprises one or more of titanium nitride (TiN), and titanium silicon nitride (TiSiN).

The titanium-containing layer 212 may have any suitable thickness. In some embodiments, the titanium-containing layer 212 has a thickness in a range of from 0 Å to 5 Å, including in a range of from >0 Å to 5 Å, in a range of from 1 Å to 5 Å, including about 1 Å, about 2 Å, about 3 Å, about 4 Å, and about 5 Å.

In one or more embodiments, an N-metal region 214 is formed on a top surface 209 of the high-κ dielectric layer 210 (or on a top surface 211 of the titanium-containing layer 212, if present) according to operation 108 of method 100, as illustrated in FIG. 1.

Referring to FIG. 3A, in one or more embodiments, the N-metal region 214 includes an N-metal layer 216 on a top surface 209 of the high-κ dielectric layer (or on a top surface 211 of the titanium-containing layer 212, of present). In one or more embodiments, the N-metal region 214 including the N-metal layer 216 may have any suitable thickness. In one or more embodiments, the N-metal region 214 including the N-metal layer 216 has thickness in a range of from >0 Å to <40 Å.

With reference to FIG. 3B, in one or more embodiments, the N-metal region 214 may include metal carbide layer 218 and a metal silicide layer 220 on a top surface 213 of the metal carbide layer 218. In one or more embodiments, the N-metal region 214 including the metal carbide layer 218 and the metal silicide layer 220 may have any suitable thickness. In one or more embodiments, the N-metal region 214 including the metal carbide layer 218 and the metal silicide layer 220 has thickness in a range of from >0 Å to <40 Å. In one or more embodiments, the metal carbide layer 218 has a thickness in a range of from >0 Å to <20 Å. In one or more embodiments, the metal silicide layer 220 has a thickness in a range of from >0 Å to <20 Å.

With reference to FIG. 3C, in one or more embodiments, the N-metal region 214 may include metal silicide layer 220 and a metal carbide layer 218 on a top surface 213 of the metal silicide layer 220. In one or more embodiments, the N-metal region 214 including the metal silicide layer 220 and the metal carbide layer 218 may have any suitable thickness. In one or more embodiments, the N-metal region 214 including the metal silicide layer 220 and the metal carbide layer 218 has thickness in a range of from >0 Å to <40 Å. In one or more embodiments, the metal carbide layer 218 has a thickness in a range of from >0 Å to <20 Å. In one or more embodiments, the metal silicide layer 220 has a thickness in a range of from >0 Å to <20 Å.

With reference to FIG. 3D, in one or more embodiments, the N-metal region 214 may include an N-metal layer 216 and an N-metal capping layer 222 on a top surface 213 of the N-metal layer 216. In one or more embodiments, the N-metal region 214 including the N-metal layer 216 and the N-metal capping layer 222 may have any suitable thickness. In one or more embodiments, the N-metal region 214 including the N-metal layer 216 and the N-metal capping layer 222 has thickness in a range of from >0 Å to <40 Å. In one or more embodiments, the N-metal layer 216 has a thickness in a range of from >0 Å to <20 Å. In one or more embodiments, the N-metal capping layer 222 has a thickness in a range of from >0 Å to <20 Å.

With reference to FIG. 3E, in one or more embodiments, the N-metal region 214 may include a titanium aluminum carbide (TiAlC) layer, an N-metal layer 216 on a top surface 215 of the titanium aluminum carbide (TiAlC) layer 224, and an N-metal capping layer 222 on a top surface 217 of the N-metal layer 216. In one or more embodiments, the N-metal region 214 including the titanium aluminum carbide (TiAlC) layer 224, the N-metal layer 216, and the N-metal capping layer 222 may have any suitable thickness. In one or more embodiments, the N-metal region 214 including the titanium aluminum carbide (TiAlC) layer 224, the N-metal layer 216, and the N-metal capping layer 222 has thickness in a range of from >0 Å to <40 Å. In one or more embodiments, the titanium aluminum carbide (TiAlC) layer 224 has a thickness in a range of from 0 Å to 10 Å, or in a range of from >0 Å to 10 Å. In one or more embodiments, the N-metal layer 216 has a thickness in a range of from >0 Å to <15 Å. In one or more embodiments, the N-metal capping layer 222 has a thickness in a range of from >0 Å to <20 Å.

With reference to FIG. 2A and FIGS. 3A to 3E, in one or more embodiments, the N-metal region 214 being formed may include a binary metal carbide film, and the method 108A of depositing the N-metal region 214 comprises exposing the semiconductor substrate to a cycle 11 comprising, at operation 12, a pulse of a metal-halide precursor or a metal organic precursor, and, at operation 16, a pulse of a reactant. In some embodiments, the semiconductor substrate is purged after each pulse at operation 14 and at operation 18. At decision point 20, the thickness of the deposited film, or number of cycles of metal halide/metal organic precursor and reactant is considered. If the deposited film has reached a predetermined thickness or a predetermined number of process cycles have been performed, the method 108A moves to operation 110 of method 10 illustrated in FIG. 1. The cycle 11 may be performed x number of times, where x is an integer in a range of from 1 to 100.

Referring to FIGS. 3A to 3E and FIG. 2B, in one or more embodiments, the N-metal region 214 being formed may include a ternary metal carbide film, and the method 108B of depositing the N-metal region 214 comprises exposing the semiconductor substrate to a cycle 30 comprising, at operation 32, a pulse of a metal-halide precursor or a metal organic precursor, at operation 36, a pulse of a reactant, at operation 40, a pulse of a metal-halide precursor or a metal organic precursor, and, at operation 44, a pulse of a reactant. In some embodiments, the semiconductor substrate is purged after each pulse at operation 34, operation 38, operation 42, and operation 46. At decision point 48, the thickness of the deposited film, or number of cycles of metal halide/metal organic precursor and reactant is considered. If the deposited film has reached a predetermined thickness or a predetermined number of process cycles have been performed, the method 108B moves to operation 110 of method 10 illustrated in FIG. 1. The cycle 30 may be performed x number of times, where x is an integer in a range of from 1 to 100.

Referring to FIGS. 2A and 2B, in one or more embodiments, in the methods 108A, 108B, the metal-halide precursor or the metal organic precursor may comprise any suitable N-metal. In one or more embodiments the metal-halide precursor or the metal organic precursor includes an N-metal selected from one or more of tantalum (Ta), aluminum (Al), titanium (Ti), niobium (Nb), lanthanum (La), strontium (Sr), yttrium (Y), zirconium (Zr), hafnium (Hf), and the like.

In one or more embodiments, the reactant used in the methods 108A, 108B may include a carbon-containing reactant that reacts with the metal-halide precursor and/or the metal organic precursor to form the N-metal film, which is a metal carbide film. Any suitable carbon-containing reactant may be used. In one or more embodiments, the carbon-containing reactant is selected from one or more of diethylzinc (DEZ), trimethyl aluminum (TMA), triethylaluminum (TEA), dimethylaluminumhydride (DMAH), tris(1,1-dimethylethyl) aluminum (trident), N,N,N′,N′-Tetramethylethylenediamine alane (TMEDAA), TBDMEDA

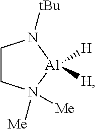

and the like.

Referring to FIGS. 3A to 3E and FIG. 2C, in one or more embodiments, the N-metal region 214 being formed may include a silicide film, and the method 108C of depositing the N-metal region 214 comprises exposing the semiconductor substrate to a cycle 50 comprising, at operation 52, a pulse of a metal-halide precursor or a metal organic precursor, and, at operation 56, a pulse of a silicon-containing reactant. In some embodiments, the semiconductor substrate is purged after each pulse at operation 54 and at operation 58. At decision point 60, the thickness of the deposited film, or number of cycles of metal halide/metal organic precursor and silicon-containing reactant is considered. If the deposited film has reached a predetermined thickness or a predetermined number of process cycles have been performed, the method 108C moves to operation 110 of method 10 illustrated in FIG. 1. The cycle 60 may be performed x number of times, where x is an integer in a range of from 1 to 100.

Referring to FIG. 2C, in one or more embodiments, in the method 108C, the metal-halide precursor or the metal organic precursor may comprise any suitable N-metal precursor. In one or more embodiments the N-metal precursor includes an N-metal selected from one or more of tantalum (Ta), aluminum (Al), titanium (Ti), niobium (Nb), lanthanum (La), strontium (Sr), yttrium (Y), zirconium (Zr), hafnium (Hf), and the like.

In one or more embodiments, the silicon-containing reactant used in the method 108C may include a silicon-containing reactant that reacts with the N-metal precursor to form a metal silicide film. Any suitable silicon-containing reactant may be used. In one or more embodiments, the silicon-containing reactant is selected from one or more of silane, disilane, 1-methyl-3,6-bis(trimethylsilyl)-1,4-cyclohexadiene, 1,4-dihydro-1,4-bis(trimethylsilyl) pyrazine, silicon tetrachloride, trimethylsilyl acetylene (TMSA), silyl aluminum compounds having a general formula of (R₃Si)ₙ—AlX₃₋ₙ NMeₚ where R is an alkyl group having from 1 to 20 carbons, n is an integer in a range of from 1 to 3, X is a halide, Me is a methyl group, and p is an integer in a range of from 1 to 3, and the like.

Referring to FIGS. 3A to 3E, in one or more embodiments, the N-metal region 214 may comprise any suitable material known to the skilled artisan. In one or more embodiments, the N-metal region 214 may include a binary metal carbide film selected from one or more of tantalum carbide (TaC), niobium carbide (NbC), titanium carbide (TiC), aluminum carbide (AlC), zirconium carbide (ZrC), strontium carbide (SrC), yttrium carbide (YC), lanthanum carbide (LaC), hafnium carbide (HfC), and the like.

In one or more embodiments, the N-metal region may include a ternary metal carbide film selected from one or more of titanium aluminum carbide (TiAlC), tantalum aluminum carbide (TaAlC), niobium aluminum carbide (NbAlC), zirconium aluminum carbide (ZrAlC), strontium aluminum carbide (SrC), yttrium aluminum carbide (YAlC), titanium tantalum carbide (TiTaC), niobium tantalum carbide (NbTaC), zirconium tantalum carbide (ZrTaC), strontium tantalum carbide (SrTaC), yttrium tantalum carbide (YTaC), and the like.

In one or more embodiments, the N-metal region 214 may include a metal silicide film selected from one or more of lanthanum silicide (LaSi), zirconium silicide (ZrSi), strontium silicide (SrSi), yttrium silicide (YSi), tantalum silicide (TaSi), lanthanum carbide (LaC), zirconium aluminum silicide (ZrAlSi), niobium aluminum silicide (NbAlSi), strontium aluminum silicide (SrAlSi), tantalum aluminum silicide (TaAlSi), and the like.

In some embodiments, referring to FIG. 1, at operation 108, the N-metal region 214 is formed on the titanium-containing layer at a temperature of less than or equal to 500° C. and at a pressure of less than or equal to 50 Torr. In some embodiments, the temperature is in a range of from 100° C. to 500° C., or in a range of from 150° C. to 450° C., in a range of from 200° C. to 400° C., or in a range of from 250° C. to 350° C. In some embodiments, the pressure is in a range of from 0 mTorr to 50 Torr, or in the range of from 100 m Torr to 50 Torr, or in the range of from 1 Torr to 40 Torr, in the range of from 10 Torr to about 35 Torr, or in the range of from 20 Torr to 30 Torr.

Referring to FIG. 3A, FIG. 3D, and FIG. 3E, the N-metal layer 216 may comprise any of the metal carbide or metal silicide materials described herein, either alone or in combination.

Referring to FIG. 3B and FIG. 3C, the metal carbide layer 218 may comprise any of the metal carbide materials described herein, either alone or in combination. The metal silicide layer 220 may comprise any of the metal silicide materials described herein, either alone or in combination.

Referring to FIG. 3D and FIG. 3E, the N-metal capping layer 222 may comprise any suitable N-metal capping material known to the skilled artisan. In one or more embodiments, the N-metal capping layer 222 may comprise one or more of titanium nitride (TiN), lanthanum nitride (LaN), hafnium nitride (HfN), zirconium nitride (ZrN), yttrium nitride (YN), strontium nitride (SrN), silicon (Si), titanium silicide (TiSi), lanthanum silicide (LaSi), hafnium silicide (HfSi), zirconium silicide (ZrSi), yttrium silicide (YSi), strontium silicide (SrSi), titanium silicon nitride (TiSiN), lanthanum silicon nitride (LaSiN), hafnium silicon nitride (HfSiN), zirconium silicon nitride (ZrSiN), yttrium silicon nitride (YSiN), strontium silicon nitride (SrSiN), graphene, hexagonal-boron nitride (h-BN), black phosphorus (BP), amorphous carbon, amorphous boron nitride (BN), indium phosphide (InP), and a transition metal dichalcogenide (TMDC). In some embodiments, the transition metal dichalcogenide (TMDC) is selected from one or more of molybdenum sulfide (MoS₂), molybdenum selenide (MoSe₂), molybdenum telluride (MoTe₂), tungsten sulfide (WS₂), tungsten selenide (WSe₂), tungsten telluride (WTe₂), tantalum sulfide (TaS₂), tantalum selenide (TaSe₂), tantalum telluride (TaTe₂), titanium sulfide (TiS₂), titanium selenide (TiSe₂), titanium telluride (TiTe₂), niobium sulfide (NbS₂), niobium selenide (NbSe₂), niobium telluride (NbTe₂), zirconium sulfide (ZrS₂), zirconium selenide (ZrSe₂), zirconium telluride (ZrTe₂), hafnium sulfide (HfS₂), hafnium selenide (HfSe₂), hafnium telluride (HfTe₂), rhenium sulfide (ReS₂), rhenium selenide (ReSe₂), rhenium telluride (ReTe₂), platinum sulfide (PtS₂), platinum selenide (PtSe₂), platinum telluride (PtTe₂), palladium sulfide (PdS₂), palladium selenide (PdSe₂), palladium telluride (PdTe₂), nickel sulfide (NiS₂), nickel selenide (NiSe₂), nickel telluride (NiTe₂), and the like. In some embodiments, the N-metal capping layer 222 includes a combination of silicon (Si) and titanium nitride (TiN), or a combination of silicon (Si) and titanium silicon nitride (TiSiN).

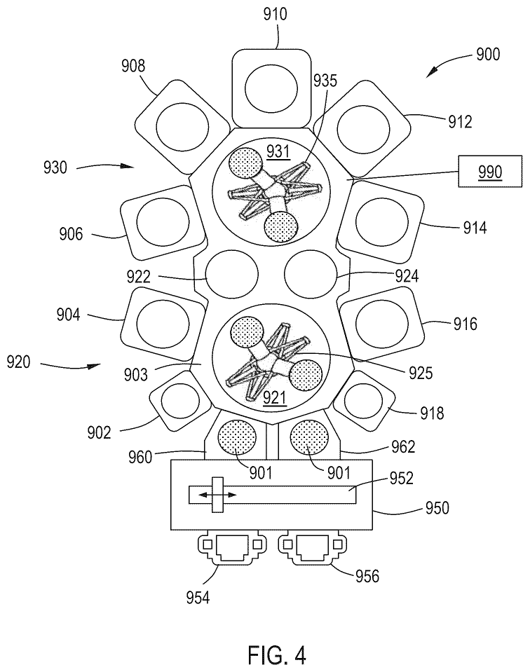

Additional embodiments of the disclosure are directed to processing tools 900 for the formation of the electronic devices and methods described, as shown in FIG. 4.

The cluster tool 900 includes at least one central transfer station 921, 931 with a plurality of sides. A robot 925, 935 is positioned within the central transfer station 921, 931 and is configured to move a robot blade and a wafer to each of the plurality of sides.

The cluster tool 900 comprises a plurality of processing chambers 902, 904, 906, 908, 910, 912, 914, 916, and 918, also referred to as process stations, connected to the central transfer station. The various processing chambers provide separate processing regions isolated from adjacent process stations. The processing chamber can be any suitable chamber including, but not limited to, a preclean chamber, a buffer chamber, transfer space(s), a wafer orienter/degas chamber, a cryo cooling chamber, a deposition chamber, annealing chamber, etching chamber, a thermal processing (RTP) chamber, a plasma oxidation chamber, a plasma nitridation chamber, and an atomic layer deposition (ALD) chamber. The particular arrangement of process chambers and components can be varied depending on the cluster tool and should not be taken as limiting the scope of the disclosure.

In the embodiment shown in FIG. 4, a factory interface 950 is connected to the front of the cluster tool 900. The factory interface 950 includes a loading chamber 954 and an unloading chamber 956 on the front 951 of the factory interface 950. While the loading chamber 954 is shown on the left and the unloading chamber 956 is shown on the right, those skilled in the art will understand that this is merely representative of one possible configuration.

The size and shape of the loading chamber 954 and unloading chamber 956 can vary depending on, for example, the substrates being processed in the cluster tool 900. In the embodiment shown, the loading chamber 954 and unloading chamber 956 are sized to hold a wafer cassette with a plurality of wafers positioned within the cassette.

A robot 952 is within the factory interface 950 and can move between the loading chamber 954 and the unloading chamber 956. The robot 952 is capable of transferring a wafer from a cassette in the loading chamber 954 through the factory interface 950 to load lock chamber 960. The robot 952 is also capable of transferring a wafer from the load lock chamber 962 through the factory interface 950 to a cassette in the unloading chamber 956. As will be understood by those skilled in the art, the factory interface 950 can have more than one robot 952. For example, the factory interface 950 may have a first robot that transfers wafers between the loading chamber 954 and load lock chamber 960, and a second robot that transfers wafers between the load lock 962 and the unloading chamber 956.

The cluster tool 900 shown has a first section 920 and a second section 930. The first section 920 is connected to the factory interface 950 through load lock chambers 960, 962. The first section 920 includes a first transfer chamber 921 with at least one robot 925 positioned therein. The robot 925 is also referred to as a robotic wafer transport mechanism. The first transfer chamber 921 is centrally located with respect to the load lock chambers 960, 962, process chambers 902, 904, 916, 918, and buffer chambers 922, 924. The robot 925 of some embodiments is a multi-arm robot capable of independently moving more than one wafer at a time. In one or more embodiments, the first transfer chamber 921 comprises more than one robotic wafer transfer mechanism. The robot 925 in first transfer chamber 921 is configured to move wafers between the chambers around the first transfer chamber 921. Individual wafers are carried upon a wafer transport blade that is located at a distal end of the first robotic mechanism.

After processing a wafer in the first section 920, the wafer can be passed to the second section 930 through a pass-through chamber. For example, chambers 922, 924 can be uni-directional or bi-directional pass-through chambers. The pass-through chambers 922, 924 can be used, for example, to cryo cool the wafer before processing in the second section 930 or allow wafer cooling or post-processing before moving back to the first section 920.

A system controller 990 is in communication with the first robot 925, second robot 935, first plurality of processing chambers 902, 904, 916, 918 and second plurality of processing chambers 906, 908, 910, 912, 914. The system controller 990 can be any suitable component that can control the processing chambers and robots. For example, the system controller 990 can be a computer including a central processing unit, memory, suitable circuits and storage.

Processes may generally be stored in the memory of the system controller 990 as a software routine that, when executed by the processor, causes the process chamber to perform processes of the present disclosure. The software routine may also be stored and/or executed by a second processor (not shown) that is remotely located from the hardware being controlled by the processor. Some or all of the method of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general-purpose computer into a specific purpose computer (controller) that controls the chamber operation such that the processes are performed.

In one or more embodiments, the processing tool 900 comprises a central transfer station 921, 931 comprising at least one robot 925, 935 configured to deposit a high-κ dielectric layer on a top surface of a channel located between a source and a drain on a semiconductor substrate; deposit a titanium-containing layer on the high-κ dielectric layer; form an N-metal region on the titanium-containing layer; optionally, anneal the semiconductor substrate; or, optionally, perform post-processing operation. In one or more embodiments, the at least one robot 925, 935 is configured to form or deposit a gate comprising one or more of a gate metal (not illustrated) or a gate contact (not illustrated) on an exposed surface of the high-κ dielectric layer after removing one or more of the N-metal region or the titanium-containing layer.

One or more embodiments of the disclosure are directed to a non-transitory computer readable medium including instructions, that, when executed by a controller of a processing chamber, cause the processing chamber to perform the operations of method 100. In some embodiments, the non-transitory computer readable medium includes instructions, that, when executed by a controller of a processing chamber, cause the processing chamber to perform the operations of: deposit high-κ dielectric layer (operation 104) on a top surface of a channel located between a source and a drain on a substrate; deposit a titanium-containing layer on the high-κ dielectric material (operation 106); and form an N-metal region on the titanium-containing layer (operation 108), the N-metal region comprising one or more of a binary metal carbide film, a ternary metal carbide film, and a metal silicide film.

In further embodiments, the non-transitory computer readable medium includes instructions, that, when executed by a controller of a processing chamber, cause the processing chamber to perform the operations of: form or deposit a gate comprising one or more of a gate metal (not illustrated) or a gate contact (not illustrated) on the exposed surface of the high-κ dielectric layer after removing one or more of the capping layer or the titanium layer.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. In one or more embodiments, the particular features, structures, materials, or characteristics are combined in any suitable manner.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A method of manufacturing a semiconductor device, the method comprising:
depositing high-κ dielectric layer on a top surface of a channel located between a source and a drain on a substrate; and
forming an N-metal region on the high-κ dielectric layer, the N-metal region comprising one or more of a binary metal carbide film, a ternary metal carbide film, and a metal silicide film.

2. The method of claim 1, wherein forming the N-metal region comprises atomic layer deposition of alternating cycles of N-metal precursor and one or more of a carbon-containing reactant or a silicon-containing reactant.

3. The method of claim 1, wherein forming the N-metal region comprises atomic layer deposition at a temperature in a range of about 200° C. to about 500° C.

4. The method of claim 2, wherein the N-metal precursor comprises an N-metal selected from one or more of tantalum (Ta), aluminum (Al), titanium (Ti), niobium (Nb), lanthanum (La), strontium (Sr), yttrium (Y), zirconium (Zr), and hafnium (Hf).

5. The method of claim 2, wherein the carbon-containing reactant comprises one or more of diethylzinc (DEZ), trimethyl aluminum (TMA), triethylaluminum (TEA), dimethylaluminumhydride (DMAH), tris(1,1-dimethylethyl) aluminum (trident), N,N,N′,N′-Tetramethylethylenediamine alane (TMEDAA), and TBDMEDA

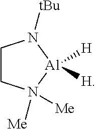

6. The method of claim 2, wherein the silicon-containing reactant comprises one or more of silane, disilane, 1-methyl-3,6-bis(trimethylsilyl)-1,4-cyclohexadiene, 1,4-dihydro-1,4-bis(trimethylsilyl) pyrazine, silicon tetrachloride, trimethylsilyl acetylene (TMSA), and silyl aluminum compounds having a general formula of (R₃Si)ₙ—AlX₃₋ₙ NMeₚ where R is an alkyl group having from 1 to 20 carbons, n is an integer in a range of from 1 to 3, X is a halide, Me is a methyl group, and p is an integer in a range of from 1 to 3.

7. The method of claim 1, further comprising forming a titanium-containing layer on the top surface of the high-κ dielectric layer.

8. The method of claim 1, wherein the N-metal region further comprises a titanium aluminum carbide (TiAlC) layer.

9. The method of claim 1, wherein the N-metal region further comprises an N-metal capping layer.

10. The method of claim 9, wherein the N-metal capping layer comprises one or more of one or more of titanium nitride (TIN), lanthanum nitride (LaN), hafnium nitride (HfN), zirconium nitride (ZrN), yttrium nitride (YN), strontium nitride (SrN), silicon (Si), titanium silicide (TiSi), lanthanum silicide (LaSi), hafnium silicide (HfSi), zirconium silicide (ZrSi), yttrium silicide (YSi), strontium silicide (SrSi), titanium silicon nitride (TiSiN), lanthanum silicon nitride (LaSiN), hafnium silicon nitride (HfSiN), zirconium silicon nitride (ZrSiN), yttrium silicon nitride (YSiN), strontium silicon nitride (SrSiN), graphene, hexagonal-boron nitride (h-BN), black phosphorus (BP), amorphous carbon, amorphous boron nitride (BN), indium phosphide (InP), and a transition metal dichalcogenide (TMDC).

11. The method of claim 1, wherein the N-metal region has a thickness of less than about 40 Å.

12. The method of claim 8, wherein the titanium aluminum carbide (TiAlC) layer has a thickness in a range of from 0 Å to 10 Å.

13. The method of claim 1, wherein the N-metal region comprises one or more of tantalum carbide (TaC), niobium carbide (NbC), titanium carbide (TiC), aluminum carbide (AlC), zirconium carbide (ZrC), strontium carbide (SrC), yttrium carbide (YC), titanium aluminum carbide (TiAlC), tantalum aluminum carbide (TaAlC), niobium aluminum carbide (NbAlC), zirconium aluminum carbide (ZrAlC), strontium aluminum carbide (SrC), yttrium aluminum carbide (YAlC), titanium tantalum carbide (TiTaC), niobium tantalum carbide (NbTaC), zirconium tantalum carbide (ZrTaC), strontium tantalum carbide (SrTaC), and yttrium tantalum carbide (YTaC), lanthanum silicide (LaSi), zirconium silicide (ZrSi), strontium silicide (SrSi), yttrium silicide (YSi), lanthanum carbide (LaC), hafnium carbide (HfC), tantalum silicide (TaSi), zirconium aluminum silicide (ZrAlSi), niobium aluminum silicide (NbAlSi), strontium aluminum silicide (SrAlSi), tantalum aluminum silicide (TaAlSi).

14. A semiconductor device comprising:
a source region, a drain region, and a channel separating the source region and drain region;
a high-κ dielectric layer on a top surface of the channel; and
an N-metal region on the high-κ dielectric layer, the N-metal region comprising one or more of a binary metal carbide film, a ternary metal carbide film, and a metal silicide film.

15. The semiconductor device of claim 14, wherein the N-metal region comprises one or more of tantalum carbide (TaC), niobium carbide (NbC), titanium carbide (TiC), aluminum carbide (AlC), zirconium carbide (ZrC), strontium carbide (SrC), yttrium carbide (YC), titanium aluminum carbide (TiAlC), tantalum aluminum carbide (TaAlC), niobium aluminum carbide (NbAlC), zirconium aluminum carbide (ZrAlC), strontium aluminum carbide (SrC), yttrium aluminum carbide (YAlC), titanium tantalum carbide (TiTaC), niobium tantalum carbide (NbTaC), zirconium tantalum carbide (ZrTaC), strontium tantalum carbide (SrTaC), and yttrium tantalum carbide (YTaC), lanthanum silicide (LaSi), zirconium silicide (ZrSi), strontium silicide (SrSi), yttrium silicide (YSi), lanthanum carbide (LaC), hafnium carbide (HfC), tantalum silicide (TaSi), zirconium aluminum silicide (ZrAlSi), niobium aluminum silicide (NbAlSi), strontium aluminum silicide (SrAlSi), tantalum aluminum silicide (TaAlSi).

16. The semiconductor device of claim 15, wherein the N-metal region further comprises a titanium aluminum carbide (TiAlC) layer.

17. The semiconductor device of claim 16, wherein the N-metal region further comprises an N-metal capping layer, the N-metal capping layer comprising one or more of one or more of titanium nitride (TiN), lanthanum nitride (LaN), hafnium nitride (HfN), zirconium nitride (ZrN), yttrium nitride (YN), strontium nitride (SrN), silicon (Si), titanium silicide (TiSi), lanthanum silicide (LaSi), hafnium silicide (HfSi), zirconium silicide (ZrSi), yttrium silicide (YSi), strontium silicide (SrSi), titanium silicon nitride (TiSiN), lanthanum silicon nitride (LaSiN), hafnium silicon nitride (HfSiN), zirconium silicon nitride (ZrSiN), yttrium silicon nitride (YSiN), strontium silicon nitride (SrSiN), graphene, hexagonal-boron nitride (h-BN), black phosphorus (BP), amorphous carbon, amorphous boron nitride (BN), indium phosphide (InP), and a transition metal dichalcogenide (TMDC).

18. The semiconductor device of claim 17, wherein the N-metal region has a thickness of less than about 40 Å, the titanium aluminum carbide (TiAlC) layer has a thickness in a range of from 0 Å to 10 Å, and the N-metal capping layer has a thickness less than about 20 Å.

19. The semiconductor device of claim 16, further comprising a titanium-containing layer on the top surface of the high-κ dielectric layer.

20. A non-transitory computer readable medium including instructions, that, when executed by a controller of a processing chamber, cause the processing chamber to perform the operations of:
deposit high-κ dielectric layer on a top surface of a channel located between a source and a drain on a substrate; and
form an N-metal region on the high-κ dielectric layer by atomic layer deposition, at a temperature in a range of about 200° C. to about 500° C., of alternating cycles of N-metal precursor and one or more of a carbon-containing reactant or a silicon-containing reactant, the N-metal region comprising one or more of a binary metal carbide film, a ternary metal carbide film, and a metal silicide film.
